(19) United States
(12) Patent Application Publication
(10) Pub. No.: US 2005/0173713 A1
(43) Pub. Date: Aug. 11, 2005

(54) Multi-pin light-emitting diode device

(76) Inventors: Ming-Der Lin, Hsinchu (TW); San Bao Lin, Jungli City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/019,169

(22) Filed: Dec. 23, 2004

(30) Foreign Application Priority Data
Feb. 6, 2004 (TW) 093102849

(51) Int. Cl. H01L 27/15

(52) U.S. Cl. 257/81

(57) ABSTRACT

A light-emitting diode (LED) device with at least three pins, mainly comprises an accommodating base provided therein with an electrostatic discharge protection device and at least one light-emitting die adhered onto this electrostatic discharge protection device in the manner of flip-chip, in such a way that a first electrode and a second electrode of the light-emitting die are electrically connected to a first protective electrode and a second protective electrode of the electrostatic discharge protection device, respectively and correspondingly. The accommodating base is connectedly provided with at least one heat-dissipating pin, and at the side of this accommodating base, a first electro-conductive pin and a second electro-conductive pin are provided, such that the first protective electrode and the second protective electrode are electrically connected thereto, respectively. As such, not only the function of prevention of electrostatic damage and high heat-dissipation efficiency may be provided, but also enhanced brightness of the LED device may be obtained.

### FIELD OF THE INVENTION

The present invention is related to a light-emitting diode (LED) device, particularly to a LED device with at least three pins, having not only an electrostatic protective effect and high heat-dissipation efficiency, but also raised brightness thereof.

### BACKGROUND

Owing to several advantages, such as small volume, low weight, low power consumption, and long service life, as examples, light-emitting diodes (LEDs) have been widely used in computer peripherals, communication products, and other electronic apparatuses.

Referring to FIG. 1, there is shown a structural diagram of a conventional dual inline package (DIP) LED device. A LED device 10, as shown in this figure, is mainly provided with a light-emitting die 11 fixed in a pyramid portion 159 of a first lead frame 151. At the side of the first lead frame 151, there is provided with a corresponding second lead frame 153. For the light-emitting die 11, a first electrode 111 and a second electrode 113 thereof are electrically connected to the corresponding first lead frame 151 and the second lead frame 153 by means of a first lead 131 and a second lead 133, respectively. Meanwhile, the light-emitting die 11, the pyramid portion 159, the first lead 131, the second lead 133, a first part of the first lead frame 151, and a part of the second lead frame 153 are housed in a protective layer 19.

When a working power source is fed into the first lead frame 151 and second lead frame 153, the light-emitting die 11 may emit a light source and project it forwardly. Although the fundamental luminescent function is provided for this LED device 10, there is no limit on voltage. Therefore, the damage to the light-emitting die 11 may occur extremely easily owing to the excessively high voltage between two terminals of the first electrode 111 and second electrode 113 of the light-emitting die 11, if an electrostatic protective effect is generated.

For avoiding such damage phenomenon to the light-emitting die 11 resulted from the electrostatic protective effect, a LED with electrostatic protective function, as shown in FIG. 2, is proposed by the industry. The main structure of such a LED device 20 with electrostatic protective function is essentially the same as the conventional structure shown in FIG. 1, except that a zener diode 27 is additionally provided at the top end of a pyramid portion 259 of a first lead frame 251, and electrically connected to the corresponding second electrode 113 and second lead frame 153 of the light-emitting die 11 by means of a second lead 233 and a third lead 235, respectively, while a second electrode 273 of the zener diode 27 is electrically connected to the first lead frame 251, directly. As such, with the operation of the zener diode 27, the current is allowed to pass through the zener diode 27 owing to breakdown and bypass effects of the zener diode 27, when the voltage between the first and second electrodes 111 and 113 of the light-emitting die 11 is excessively high. Further, the LED 11 is protected from damage accordingly.

How to discharge heat, generated when irradiating, in order to keep the temperature of the light emitting die at an approximate working temperature becomes an important issue as the luminous emittance increases, because the increasing area of the light-emitting die or the larger working current supplied therefor has become a tendency for increasing the luminous emittance of the LED device. Although a simple electrostatic protective function is provided in the aforementioned LED, the raised working temperature, and thus the lowered luminous efficiency of the light-emitting die may occur easily, due to the fact that it is incapable of discharging heat generated along with irradiance timely. Moreover, the first lead 131, the first electrode 111, and the second lead 233 are placed on the projection path of the light source, in such a way that the shading effect may occur extremely easily, thus lowering brightness of the LED device 20 correspondingly.

### SUMMARY OF THE INVENTION

For this purpose, how to design a novel light-emitting diode (LED) device, which may not only have the effect of preventing electrostatic damage, but also provide a superior heat-dissipating path, and enhance brightness thereof, aiming at the disadvantages of the above conventional art, is the key point of the present invention.

Accordingly, it is the primary object of the present invention to provide a multi-pin LED device including an accommodating base connectedly provided with at least one outwardly-extending heat-dissipating pin served for timely and directly discharging the working heat source, generated by a light-emitting die disposed within the accommodating base, and then controlling the temperature of the light-emitting device at an appropriate working temperature, in order to enhance the luminous efficiency.

It is the secondary object of the present invention to provide a multi-pin LED device having heat-dissipation function and electro-conductive pins disposed independently among each other, so as to eliminate the safety problem of electric leakage, which may occur if the heat-dissipation function and the electroconductivity are provided by a common pin.

It is another object of the present invention to provide a multi-pin LED device capable of being produced massively by means of an existed manufacturing process without additionally invested vast cost.

It is still another object of the present invention to provide a multi-pin LED device having light-emitting dies adhered onto an electrostatic discharge protection device in the manner of flip-chip, in such a way that the block for the projection light source provided by a first lead wire and a second lead wire is avoided, further enhancing brightness of the LED device.

For the purpose of achieving aforementioned objects, the present invention provides a multi-pin LED device, the main structure thereof comprising: an electrostatic discharge protection device having a first protective electrode and a second protective electrode; at least one light-emitting die fixedly provided on the electrostatic discharge protection device, the first electrode and the second electrode of each light-emitting die capable of being electrically connected to the corresponding first protective electrode and second protective electrode, respectively; an accommodating base used to fix the light-emitting die and the electrostatic discharge protection device, and connectedly provided with at least one heat-dissipating pin at the bottom thereof; at least one first electro-conductive pin electrically connected to the first protective electrode; and at least one second electro-conductive pin electrically connected to the second protective electrode.

### BRIEF DESCRIPTION OF DRAWINGS

FIG. 1 is a structural diagram of a conventional light-emitting diode (LED) device;

FIG. 2 is a structural diagram of another conventional LED device; and

FIG. 3 is a structural diagram according to one preferred embodiment of the present invention.

FIG. 4 is a structural diagram according to another embodiment of the present invention.

FIG. 5 is a circuit diagram according to the embodiment shown in FIG. 3.

FIG. 6 is a diagram illustrating voltage-current relation of an electrostatic discharge protection device according to the embodiment shown in FIG. 5.

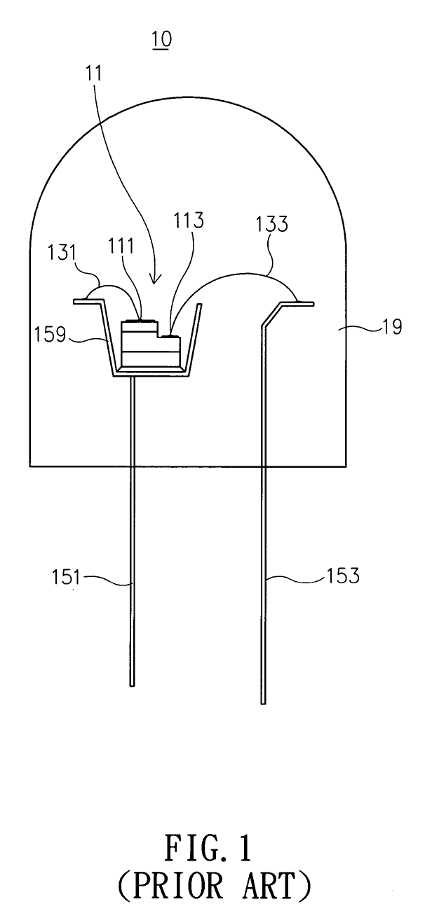

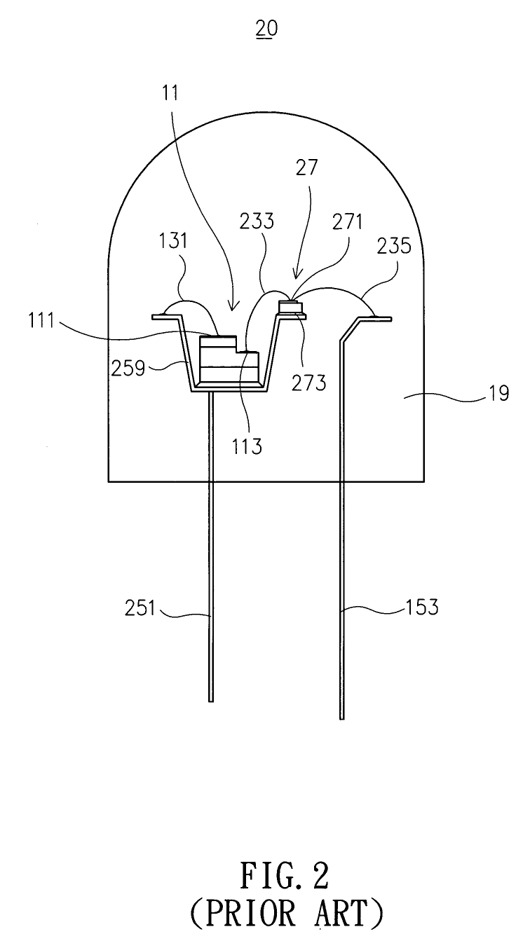

### DETAILED DESCRIPTION

The structural features and the effects to be achieved may further be understood and appreciated by reference to the presently preferred embodiments together with the detailed description.

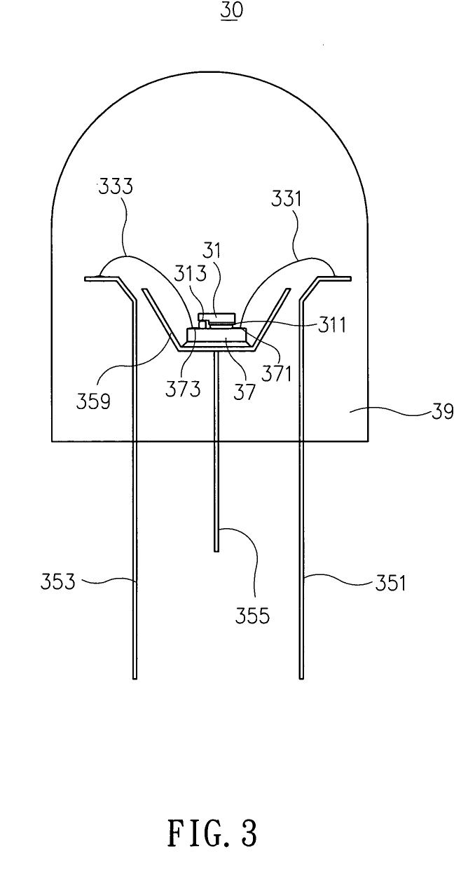

Referring to FIG. 3, firstly, there is shown a structural diagram according to one preferred embodiment of the present invention. The main structure of a light-emitting diode (LED) device 30, as shown in this figure, having high heat-dissipation efficiency and electrostatic protective effect, comprises at least one electrostatic discharge protection device 37, at least one light-emitting die 31, a first electro-conductive pin 351, a second electro-conductive pin 353, and at least one accommodating base 359.

The light-emitting die 31 includes a first electrode 311 and a second electrode 313, while the electrostatic discharge protection device 37 at least includes a first protective electrode 371 and a second protective electrode 373. For the light-emitting die 31, the flip-chip method is used such that the first electrode 311 and the second electrode 313 of the light-emitting die 31 may be electrically connected to the corresponding first protective electrode 371 and the second protective electrode 373, respectively.

By means of silver adhesive, solder paste, AuSi, AuSn, or other thermally conductive materials, the electrostatic discharge protection device 37 may be directly adhered to the bottom of the accommodating base 359 provided with a heat-dissipating pin 355 extending outwardly. At the side of the accommodating base 359, there are provided with the first electro-conductive pin 351 and the second electro-conductive pin 353, to which the first protective electrode 371 and the second protective electrode 373 are electrically connected, correspondingly, via a first lead wire 331 and a second lead wire 333, respectively. The projection path from the light source may be not blocked by the first and second lead wires 331 and 333, resulting in raised brightness of the light-emitting element, due to the fact that the light-emitting die 31 is adhered onto the electrostatic discharge protection device 37 in the manner of flip-chip.

Moreover, on the exterior of the light-emitting die 31, electrostatic discharge protection device 37, accommodating base 359, first lead wire 331, second lead wire 333, top end of the first electro-conductive pin 351, and top end of the second electro-conductive pin 353, there may be provided with a protective layer 39 made from the material, such as glass, plastic, epoxy, for example, in order to protect internal structure from being damaged by the contact with external air. The protective layer 39 is also made as a convex lens, concave lens, and so forth, in such a way that the beam projected from the light-emitting die 31 may be uniformly dispersed or concentratedly projected depending upon the actual purpose.

Owing to AuSi, AuSn, silver adhesive, solder paste, or other adhesive material with high coefficient of thermal conductivity, which may be used to bond the electrostatic discharge protection device 37 onto the inner side of the accommodating base 387, in addition to the material with high coefficient of thermal conductivity, for instance Cu, Al, etc., which may be used to produce the accommodating base 359 and the heat-dissipating pin 355 extendingly outside of the protective material 39 therefrom, the heat source generated from the light-emitting die 31 may be discharged rapidly via the accommodating base 359 and the heat-dissipating pin 355, enabling the light-emitting die 31 to maintain a constant working temperature, further keeping the light-emitting die 31 at a constant working temperature. Therefore, increased luminous efficiency and prolonged service life may be obtained.

It is important for the heat to be transmitted to a circuit board (not shown) from the first electro-conductive pin 351, thus avoiding temperature rising of the circuit board, if the LED device 30 is installed on the circuit board, because the first electro-conductive pin 351 and the heat-dissipating pin 355 of the present invention are not interconnected together. Moreover, for the heat-dissipating pin 355 itself, no additional high working temperature is generated because it is not electrified, thereby the heat-dissipation effect of the light-emitting die is not affected. Meanwhile, the safety problem resulted from electric leakage may be avoided owing to independent heat-dissipation function and nonconductivity inherent to the heat-dissipating pin 355. An enhanced heat-dissipation effect may be achieved, of course, if the circuit board is designed with a heat-dissipating device (not shown) to which the heat-dissipating pin 355 may be also connected.

In addition, for the light-emitting die 31 which generates lower working temperature, it is still possible to connect one of the first electro-conductive pin 351 and the second electro-conductive pin 353 to the thermally conductive pin directly 355. As such, heat may be transmitted to a heat-dissipating device (not shown) on the circuit board via this one of the first electro-conductive pin 351 and the second electro-conductive pin 353.

The light-emitting die 31 is fixedly provided on the electrostatic discharge protection device 37 in the manner of flip-chip in the above embodiment, though, the light-emitting die 31 may be fixedly provided on the accommodating base 359 directly such that the first electrode 311 and the second electrode 313 of the light-emitting die 31 are directly and electrically connected to the first electro-conductive pin 351 and the second electro-conductive pin 353, correspondingly, as well, in another application field, if misgivings about the damage to the device resulted from the effect of electrostatic discharge may not present. Therefore, the working heat source generated from the light-emitting die 31 may be still discharged rapidly via the heat-dissipating pin 355.

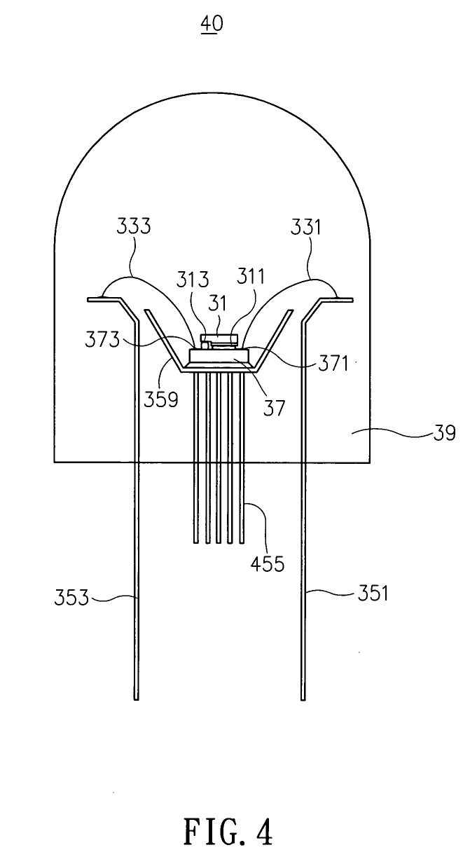

Subsequently, referring to FIG. 4, there is shown a structural diagram according to another embodiment of the present invention. As illustrated in this figure, the main structure of the LED device 40 is approximately the same as that of the above embodiment in FIG. 3. A plurality of heat-dissipating pins 455, however, may be extendingly provided at the bottom of the accommodating base 359 in order to enhance heat-dissipation effect. Although the heat-dissipating pin 455 is provided at the bottom of the accommodating base 359 in this figure, but not limited thereto. Instead, it should be understood that the location of the heat-dissipating pin 455 may be designed at the side of the accommodating base 359 and the number thereof may be changed depending on the amount of the light-emitting die 31 within the accommodating base 359, heating speed, and direction of heat transfer, thereby suitable for practical products.

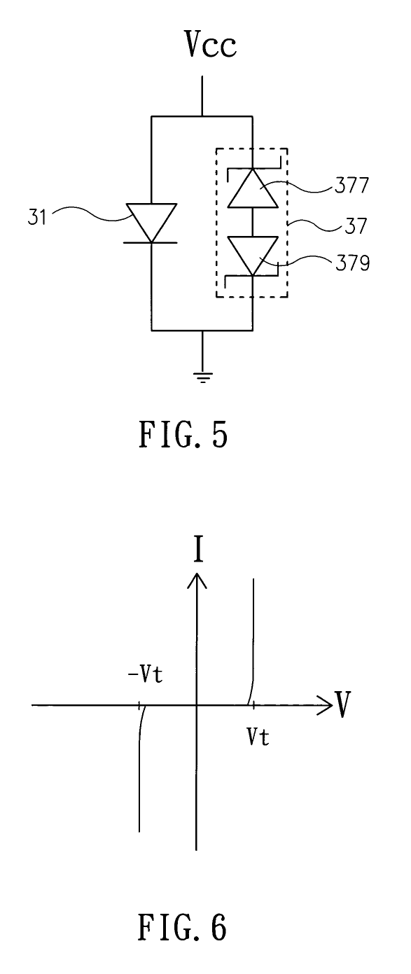

Finally, referring to FIG. 5 together with FIG. 6, there are shown a circuit diagram and a diagram illustrating voltage-current relation of an electrostatic discharge protection device, respectively, according to the embodiment of the present invention shown in FIG. 3. As illustrated in these figures, the electrostatic discharge protection device 37 and the light-emitting die 31 are electrically connected in parallel, while the former is selectively composed of a plurality of back-to-back zener diodes 377, 379. Therefore, the electrostatic discharge protection device 37 may be turned on allowing the working current to flow therethrough, when the supply voltage Vcc is larger than the positive voltage limit Vt of the electrostatic discharge protection device 37 or smaller than the negative voltage limit −Vt thereof. Then, the voltage between two ends of the light-emitting die 31 may be confined, avoiding the damage to the light-emitting die 31. Although one electrostatic discharge protection device 37 is composed of two back-to-back zener diodes in the present invention, but it is not limited thereto in practical practice, whereas Schottky diodes, electrostatic discharge (ESD) protection integrated circuits (ICs), voltage limiters, or other equivalent diodes may be utilized as desired and connected in series, in parallel, or in other ways, to function as the electrostatic discharge protection device, which is allowed to cooperate with various driving voltages of the light-emitting dies and then prevent them from being damaged.

Owing to the simple structure, high reliability, such a LED device having both of the electrostatic protective function and high heat-dissipation efficiency may be produced by the existed manufacturing equipment without investing additional vast cost.

The foregoing description is merely one embodiment of present invention and not considered as restrictive. All equivalent variations and modifications in process, method, feature, and spirit in accordance with the appended claims may be made without in any way from the scope of the invention.

### LIST OF REFERENCE SYMBOLS

10 light-emitting diode device
11 light-emitting die
111 first electrode
113 second electrode
131 first lead
133 second lead
151 first lead frame
153 second lead frame
159 pyramid portion
19 protective layer
20 light-emitting diode device
233 second lead
235 third lead
253 first lead frame
259 pyramid portion
27 zener diode
271 first electrode
273 second electrode
30 light-emitting diode device
31 light-emitting die
311 first electrode
313 second electrode
331 first lead
333 second lead
351 first electro-conductive pin
353 second electro-conductive pin
355 heat-dissipating pin
359 accommodating base
37 electrostatic discharge protection device
371 first protective electrode
373 second protective electrode
377 zener diode
379 zener diode
39 protective layer
40 light-emitting diode device
45 heat-dissipating pins

1. A multi-pin light-emitting diode (LED) device, comprising:
an electrostatic discharge protection device having a first protective electrode and a second protective electrode;
at least one light-emitting die fixedly provided on said electrostatic discharge protection device, a first electrode and a second electrode of each of said light-emitting dies electrically connected to said first protective electrode and said second protective electrode, correspondingly and respectively;
an accommodating base for fixing said light-emitting die as well as said electrostatic discharge protection device, and connectedly provided at the bottom thereof with at least one heat-dissipating pin;
at least one first electro-conductive pin electrically connected to said first protective electrode; and
at least one second electro-conductive pin electrically connected to said second protective electrode.

2. The LED device according to claim 1, wherein said light-emitting die is adhered onto said electrostatic discharge protection device in the manner of flip-chip.

3. The LED device according to claim 1, wherein said electrostatic discharge protection device is fixedly provided on said accommodating base further by means of a material selected from the group consisting of solder paste, silver adhesive, thermally conductive adhesive, AuSi, AuSn, and the combination thereof.

4. The LED device according to claim 1, further comprising a protective layer allowed to house said electrostatic discharge protection device, said light-emitting die, said accommodating base, a part of said first electro-conductive pin, a part of said second electro-conductive pin, and a part of said heat-dissipating pin.

5. The LED device according to claim 4, wherein said protective layer is made from a material selected from the group consisting of glass, plastic, epoxy, and the combination thereof.

6. The LED device according to claim 1, wherein said first protective electrode and said second protective electrode are electrically connected to said first electro-conductive pin and said second electro-conductive pin, correspondingly, via a first lead wire and a second lead wire, respectively.

7. The LED device according to claim 1, wherein said electrostatic discharge protection device is selected from the group consisting of an electrostatic discharge (ESD) protection integrated circuit (IC), Schottky barrier diode, zener diode, voltage limiter, equivalent diode, and the combination thereof.

8. The LED device according to claim 1, wherein said heat-dissipating pin is connectedly provided at the side of said accommodating base.

9. The LED device according to claim 1, wherein said heat-dissipating pin is also selectively combined with one of said first electro-conductive pin and said second electro-conductive pin as a unit.

10. The LED device according to claim 1, wherein said accommodating base is only connectedly provided with one single heat-dissipating pin.

11. A multi-pin light-emitting diode (LED) device, comprising:
an accommodating base connectedly provided at least one heat-dissipating pin;
at least one light-emitting die fixedly provided on said accommodating base, each at least having a first electrode and a second electrode;
at least one first electro-conductive pin electrically connected to said first protective electrode; and
at least one second electro-conductive pin electrically connected to said second protective electrode.
